(19) United States
(12) Patent Application Publication
(10) Pub. No.: US 2025/0287767 A1
(43) Pub. Date: Sep. 11, 2025

(54) LIGHT SOURCE AND SUBSTRATE

(71) Applicant: NICHIA CORPORATION, Anan-shi (JP)

(72) Inventors: Masahito KOMATSUBARA, Anan-shi (JP); Daisuke IWAKURA, Komatsushima-shi (JP)

(73) Assignee: NICHIA CORPORATION, Anan-shi (JP)

(21) Appl. No.: 19/064,687

(22) Filed: Feb. 27, 2025

(30) Foreign Application Priority Data
Mar. 7, 2024 (JP) 2024-035042

(51) Int. Cl. H10H 29/85; H10H 29/49

(52) U.S. Cl. CPC H10H 29/8585; H10H 29/49

(57) ABSTRACT

A light source includes a substrate, a light-emitting device, and a first bonding member. The first bonding member is disposed between a first electrode of the light-emitting device and a first upper surface of a first metal member of the substrate to bond the first electrode and the first metal member, and is disposed between a second electrode of the light-emitting device and a second upper surface of a second metal member of the substrate to bond the second electrode and the second metal member. An upper portion of the insulating member of the substrate is located between the first electrode and the second electrode of the light-emitting device. Each of the first lower surface of the first metal member, the second lower surface of the second metal member, and the lower portion of the insulating member is exposed.

### CROSS-REFERENCE TO RELATED APPLICATIONS

The present application claims priority under 35 U.S.C. § 119 to Japanese Patent Application No. 2024-035042, filed Mar. 7, 2024, the contents of which is hereby incorporated by reference in its entirety.

### BACKGROUND

### 1. Technical Field

The present invention relates to a light source and a substrate.

### 2. Description of Related Art

Japanese Patent Publication No. 2022-102279 describes a configuration in which a protruding member having insulating properties is provided between a first electrode and a second electrode of an LED chip.

### SUMMARY

Embodiments of the present invention can provide a light source and a substrate that can improve heat dissipation.

According to one aspect of the present invention, a light source includes a substrate, a light-emitting device disposed on the substrate, and a first bonding member disposed between the substrate and the light-emitting device. The substrate includes a first metal member having a first upper surface and a first lower surface located on a side opposite to the first upper surface, a second metal member having a second upper surface and a second lower surface located on a side opposite to the second upper surface, the second metal member being spaced apart from the first metal member in a first direction, and an insulating member including a lower portion located between the first metal member and the second metal member in the first direction, and an upper portion extending, from the lower portion, to be higher than the first upper surface and the second upper surface. The light-emitting device includes a semiconductor layered body having a first element surface facing the substrate and a second element surface located on a side opposite to the first element surface, a first electrode disposed at the first element surface, and a second electrode disposed at the first element surface to be spaced apart from the first electrode in the first direction. The first bonding member is disposed between the first electrode and the first upper surface of the first metal member and bonds the first electrode and the first metal member and is disposed between the second electrode and the second upper surface of the second metal member and bonds the second electrode and the second metal member. The upper portion of the insulating member is located, in the first direction, between the first electrode and the second electrode of the light-emitting device. Each of the first lower surface of the first metal member, the second lower surface of the second metal member, and the lower portion of the insulating member is exposed.

According to another aspect of the present invention, a substrate includes a first metal member having a first upper surface and a first lower surface located on a side opposite to the first upper surface, a second metal member having a second upper surface and a second lower surface located on a side opposite to the second upper surface, the second metal member being spaced apart from the first metal member in a first direction, and an insulating member including a lower portion located between the first metal member and the second metal member in the first direction, and an upper portion extending, from the lower portion, to be higher than the first upper surface and the second upper surface. A width, in the first direction, of the lower portion of the insulating member is greater than a width, in the first direction, of the upper portion of the insulating member. The lower portion of the insulating member has a first lower lateral surface facing an inner lateral surface of the first metal member and a second lower lateral surface facing an inner lateral surface of the second metal member. The substrate further includes a bonding member bonding the inner lateral surface of the first metal member and the first lower lateral surface and bonding the inner lateral surface of the second metal member and the second lower lateral surface, the bonding member being located at an upper surface of the lower portion of the insulating member.

According to an aspect of the present invention, a light source and a substrate that can improve heat dissipation can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic plan view illustrating a light source according to an embodiment.

FIG. 2 is a schematic cross-sectional view taken along a line II-II in FIG. 1.

FIG. 3 is a schematic cross-sectional view illustrating a light source according to a variation of the embodiment.

FIG. 4 is a schematic plan view illustrating a step of a method for manufacturing a substrate according to an embodiment.

FIG. 5 is a schematic cross-sectional view taken along a line V-V in FIG. 4.

FIG. 6 is a schematic cross-sectional view illustrating a step of the method for manufacturing the substrate according to the embodiment.

FIG. 7 is a schematic cross-sectional view illustrating a step of the method for manufacturing the substrate according to the embodiment.

FIG. 8 is a schematic cross-sectional view illustrating a step of the method for manufacturing the substrate according to the embodiment.

FIG. 9 is a schematic cross-sectional view illustrating a step of the method for manufacturing the substrate according to the embodiment.

FIG. 10 is a schematic cross-sectional view illustrating a step of the method for manufacturing the substrate according to the embodiment.

FIG. 11 is a schematic cross-sectional view illustrating a step of the method for manufacturing the substrate according to the embodiment.

### DETAILED DESCRIPTION OF EMBODIMENT

Embodiments of the present invention will be described below with reference to the drawings. The following embodiments are merely examples for embodying the technical concept of the present invention, and the present invention is not limited to the following embodiments. Further, dimensions, materials, shapes, relative arrangements, or the like of constituent members described in the embodiments are not intended to limit the scope of the present disclosure thereto, unless otherwise specified, and are merely exemplary. Note that the size, positional relationship, or the like of members illustrated in each of the drawings may be exaggerated for clarity of description. Further, in the following description, members having the same terms and reference characters represent the same members or members of the same quality, and a detailed description of these members will be omitted as appropriate. As a cross-sectional view, an end view illustrating only a cut surface may be illustrated.

In the following description, terms indicating specific directions or positions (e.g., “upper”, “lower”, and other terms including those terms) may be used. However, these terms are used merely to make it easy to understand relative directions or positions in the referenced drawing. As long as the relative direction or position is the same as that described in the referenced drawing using the term such as “upper” or “lower”, in drawings other than the drawings of the present disclosure, actual products, and the like, components need not be arranged in the same manner as that in the referenced drawing. For example, on the assumption that there are two members, the positional relationship expressed as “upper (or lower)” in the present specification may include a case in which the two members are in contact with each other and a case in which the two members are not in contact with each other and one of the two members is located above (or below) the other of the two members. Further, in the present specification, unless otherwise specified, a case in which a member covers an object to be covered includes a case in which the member is in contact with the object to be covered and directly covers the object to be covered, and a case in which the member is not in contact with the object to be covered and indirectly covers the object to be covered. Further, in the present specification, a width in a specific direction represents a maximum width in the specific direction.

In the drawings described below, a direction along an X-axis is referred to as a first direction X, and the first direction X indicates a predetermined direction in a plane parallel to a light-emitting surface of a light source according to an embodiment.

A direction along a Y-axis is referred to as a second direction Y, and the second direction Y indicates a direction orthogonal to the first direction X in the plane parallel to the light-emitting surface. A direction along a Z-axis is referred to as a third direction Z, and the third direction Z indicates a direction orthogonal to the above-described light-emitting surface.

### Light Source

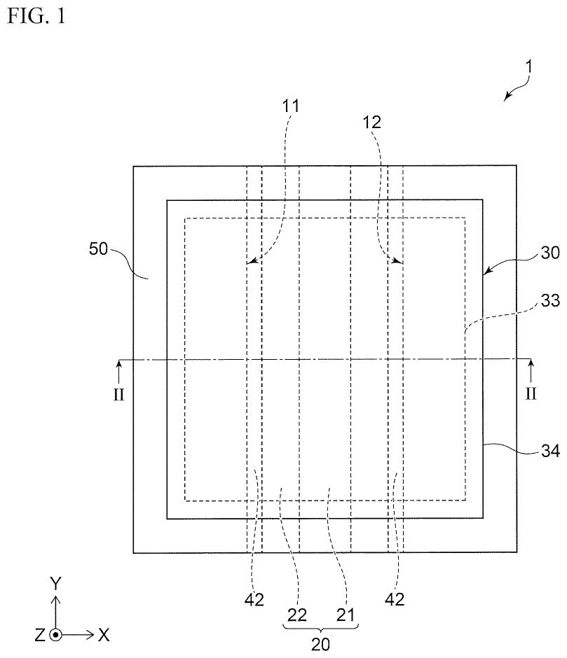

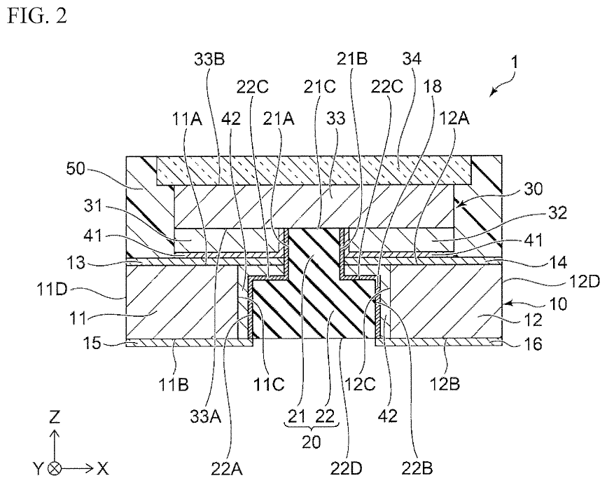

A light source 1 according to a first embodiment will be described with reference to FIGS. 1 and 2. The light source 1 includes a substrate 10, a light-emitting device 30 disposed on the substrate 10, and a first bonding member 41 disposed between the substrate 10 and the light-emitting device 30.

### Light-Emitting Device

The light-emitting device 30 includes a semiconductor layered body 33, a first electrode 31, and a second electrode 32. The light-emitting device 30 is, for example, a light-emitting diode (LED). Alternatively, the light-emitting device 30 can be a laser diode (LD).

The semiconductor layered body 33 has a first element surface 33A facing the substrate 10, and a second element surface 33B located on a side opposite to the first element surface 33A in the third direction Z.

The semiconductor layered body 33 includes a nitride semiconductor. In the present specification, it is assumed that examples of the nitride semiconductor include semiconductors having all compositions of a chemical formula expressed by InₓAl_{y}Ga_{1-x-y}N (0≤x≤1, 0≤y≤1, x+y≤1) in which the composition ratios of x and y are changed within the respective ranges. Further, it is assumed that examples of the nitride semiconductor also include a semiconductor further containing a group V element other than nitrogen (N) in the chemical formula described above, and a semiconductor further containing, in the chemical formula described above, various elements added to control various physical properties such as the conductivity type of the semiconductor. The semiconductor layered body 33 includes an n-side semiconductor layer, a p-side semiconductor layer, and an active layer located between the n-side semiconductor layer and the p-side semiconductor layer. The active layer is a light-emitting layer that emits light and has a multiple quantum well (MQW) structure including a plurality of barrier layers and a plurality of well layers, for example. Light emitted by the active layer is visible light or ultraviolet light, for example.

The first electrode 31 is disposed at the first element surface 33A. The second electrode 32 is disposed at the first element surface 33A so as to be spaced apart from the first electrode 31 in the first direction X. The first electrode 31 is a cathode electrode in the light-emitting device 30, and is electrically connected to the n-side semiconductor layer in the semiconductor layered body 33. The second electrode 32 is an anode electrode in the light-emitting device 30, and is electrically connected to the p-side semiconductor layer in the semiconductor layered body 33. As a material of the first electrode 31 and the second electrode 32, gold, platinum, silver, aluminum, nickel, titanium, or the like can be used, for example.

The light-emitting device 30 can include an element substrate such as a sapphire substrate, a gallium nitride substrate, a silicon substrate, or the like, on the second element surface 33B of the semiconductor layered body 33. For example, when the element substrate is a sapphire substrate, the element substrate can be removed using a laser lift-off method, and the light-emitting device 30 may not include the element substrate.

### Substrate

The substrate 10 includes a first metal member 11, a second metal member 12, and an insulating member 20. The substrate 10 supports the light-emitting device 30. Further, the substrate 10 is also a wiring member that electrically connects the light-emitting device 30 to an external circuit.

The first metal member 11 has a first upper surface 11A and a first lower surface 11B. The first upper surface 11A faces the first electrode 31 of the light-emitting device 30 in the third direction Z. The first lower surface 11B is located on a side opposite to the first upper surface 11A in the third direction Z. Further, the first metal member 11 has an inner lateral surface 11C and an outer lateral surface 11D located on a side opposite to the inner lateral surface 11C in the first direction X.

The second metal member 12 has a second upper surface 12A and a second lower surface 12B. The second upper surface 12A faces the second electrode 32 of the light-emitting device 30 in the third direction Z. The second lower surface 12B is located on a side opposite to the second upper surface 12A in the third direction Z. Further, the second metal member 12 has an inner lateral surface 12C facing the inner lateral surface 11C of the first metal member 11 in the first direction X, and an outer lateral surface 12D located on a side opposite to the inner lateral surface 12C in the first direction X.

The first metal member 11 can include a plating 13 facing the first electrode 31 in the third direction Z, and the surface of the plating 13 can be the first upper surface 11A. The first metal member 11 can include a plating 15 located on a side opposite to the plating 13 in the third direction Z, and the surface of the plating 15 can be the first lower surface 11B. The second metal member 12 can include a plating 14 facing the second electrode 32 in the third direction Z, and the surface of the plating 14 can be the second upper surface 12A. The second metal member 12 can include a plating 16 located on a side opposite to the plating 14 in the third direction Z, and the surface of the plating 16 can be the second lower surface 12B. When the first metal member 11 and the second metal member 12 include the plating, a first bonding member 41 described below is less likely to diffuse into the first metal member 11 and the second metal member 12, and generation of voids in the first bonding member 41 can be reduced. The platings 13, 14, 15, and 16 contain, for example, at least one metal selected from nickel (Ni), palladium (Pd), titanium (Ti), platinum (Pt), and gold (Au). Among them, nickel is effective in suppressing the diffusion of the first bonding member 41. When the first bonding member 41 does not easily wet and spread with respect to nickel, palladium or gold can be further formed on nickel in order to make the first bonding member 41 easily wet and spread.

As illustrated in FIG. 1, the first metal member 11 and the second metal member 12 are spaced apart from each other in the first direction X. The first metal member 11 and the second metal member 12 extend in the second direction Y. The first metal member 11 and the second metal member 12 contain, for example, at least one metal selected from copper (Cu) and aluminum (Al).

The insulating member 20 includes a lower portion 22 and an upper portion 21. The upper portion 21 is located on the lower portion 22 in the third direction Z. The lower portion 22 and the upper portion 21 extend in the second direction Y. The insulating member 20 is made of, for example, a ceramic. The insulating member 20 is, for example, a ceramic sintered compact in which the lower portion 22 and the upper portion 21 are integrally provided. The insulating member 20 includes, for example, silicon nitride, aluminum oxide, aluminum nitride, silicon carbide, or silicon oxide. Alternatively, the insulating member 20 can be made of a metal covered with a ceramic, glass, or a resin.

The lower portion 22 of the insulating member 20 is located between the first metal member 11 and the second metal member 12 in the first direction X. The lower portion 22 has a first lower lateral surface 22A facing the inner lateral surface 11C of the first metal member 11, and a second lower lateral surface 22B facing the inner lateral surface 12C of the second metal member 12.

The upper portion 21 extends from the lower portion 22 in the third direction Z, so as to be higher than the first upper surface 11A of the first metal member 11 and the second upper surface 12A of the second metal member 12. The upper portion 21 has an upper surface 21C facing the first element surface 33A of the semiconductor layered body 33. A part, on the upper surface 21C side, of the upper portion 21 is located between the first electrode 31 and the second electrode 32 of the light-emitting device 30 in the first direction X. The upper portion 21 has a first upper lateral surface 21A facing an inner lateral surface of the first electrode 31, and a second upper lateral surface 21B facing an inner lateral surface of the second electrode 32.

The lower portion 22 has a lower surface 22D located on a side opposite to the upper surface 21C of the upper portion 21 in the third direction Z. Each of the first lower surface 11B of the first metal member 11, the second lower surface 12B of the second metal member 12, and the lower surface 22D of the lower portion 22 of the insulating member 20 is exposed.

The light source 1 can be disposed on a mounting substrate. The first lower surface 11B of the first metal member 11, the second lower surface 12B of the second metal member 12, and the lower surface 22D of the lower portion 22 of the insulating member 20 face a mounting surface of the mounting substrate. The first lower surface 11B of the first metal member 11 and the second lower surface 12B of the second metal member 12 are bonded to a wiring portion of the mounting substrate by a bonding member such as solder. Accordingly, the first metal member 11 and the second metal member 12 are electrically connected to the wiring portion of the mounting substrate.

The width, in the first direction X, of the upper portion 21 of the insulating member 20 disposed between the first electrode 31 and the second electrode 32 of the light-emitting device 30 is smaller than the width, in the first direction X, between the first electrode 31 and the second electrode 32. The width, in the first direction X, of the lower portion 22 of the insulating member 20 is greater than the width, in the first direction X, of the upper portion 21 of the insulating member 20. Accordingly, the spacing distance, in the first direction X, between the first lower surface 11B of the first metal member 11 and the second lower surface 12B of the second metal member 12 can be made greater than the distance between the electrodes of the light-emitting device 30, and thus the first lower surface 11B and the second lower surface 12B become less likely to short-circuit on the mounting substrate due to a bonding member.

### First Bonding Member

The first bonding member 41 has conductivity. As the first bonding member 41, solder can be used, for example. The solder includes, for example, a gold-tin alloy. Alternatively, as the first bonding member 41, a mixture of a resin and metal particles can be used. As the metal particles, for example, silver particles can be used.

The first bonding member 41 is disposed between the first electrode 31 of the light-emitting device 30 and the first upper surface 11A of the first metal member 11, and bonds the first electrode 31 and the first metal member 11. When the first metal member 11 includes the plating 13, the first bonding member 41 is bonded to the plating 13. The first electrode 31 is electrically connected to the first metal member 11 via the first bonding member 41.

The first bonding member 41 is disposed between the second electrode 32 of the light-emitting device 30 and the second upper surface 12A of the second metal member 12, and bonds the second electrode 32 and the second metal member 12. When the second metal member 12 includes the plating 14, the first bonding member 41 is bonded to the plating 14. The second electrode 32 is electrically connected to the second metal member 12 via the first bonding member 41.

The semiconductor layered body 33 including the active layer in the light-emitting device 30 generates heat when it emits light. The heat generated by the semiconductor layered body 33 is dissipated to the first metal member 11 via the first electrode 31 and the first bonding member 41, and is dissipated to the second metal member 12 via the second electrode 32 and the first bonding member 41.

Furthermore, according to the present embodiment, the heat generated by the semiconductor layered body 33 can be transferred to the insulating member 20. The heat transferred from the semiconductor layered body 33 to the insulating member 20 can be transferred to the first electrode 31, the second electrode 32, the first metal member 11, and the second metal member 12, which are made of a metal material having a higher thermal conductivity than that of the insulating member 20. Further, when the lower surface 22D of the lower portion 22 is in contact with the mounting surface of the mounting substrate, heat can be directly transferred from the insulating member 20 to the mounting substrate.

An inter-electrode region of the first element surface 33A located between the first electrode 31 and the second electrode 32 of the semiconductor layered body 33 is a region in which heat cannot be dissipated to the substrate 10 via the first electrode 31 and the second electrode 32 and heat is more likely to be concentrated than in regions of the first element surface 33 A in which the first electrode 31 and the second electrode 32 are disposed. According to the present embodiment, heat can be dissipated to the substrate 10 via the insulating member 20 in such an inter-electrode region. The heat generated by the semiconductor layered body 33 can be efficiently transferred to the substrate 10 by dispersing the heat via a path passing through the first electrode 31, the second electrode 32, and the insulating member 20, and the heat can be made less likely to be concentrated in the inter-electrode region of the semiconductor layered body 33. Accordingly, the temperature of the active layer (junction temperature) can be reduced, and the light emission efficiency and reliability can be improved. Further, the improved reliability allows increased input power and improved optical output.

The first bonding member 41 preferably bonds the inner lateral surface of the first electrode 31 and the upper part of the first upper lateral surface 21A of the insulating member 20, and bonds the inner lateral surface of the second electrode 32 and the upper part of the second upper lateral surface 21B of the insulating member 20. Accordingly, heat can be easily transferred from the insulating member 20 to the first electrode 31 and the second electrode 32 via the first bonding member 41.

The upper surface 21C of the upper portion 21 of the insulating member 20 can be in contact with the first element surface 33A of the semiconductor layered body 33 directly or via an adhesive layer having thermal conductivity. Accordingly, the heat generated by the semiconductor layered body 33 can be easily transferred to the insulating member 20. As the adhesive layer having thermal conductivity, for example, a resin layer in which ceramics are dispersed, or a ceramic adhesive layer can be used.

The substrate 10 can further include a second bonding member 42. The second bonding member 42 bonds the inner lateral surface 11C of the first metal member 11 and the first lower lateral surface 22A of the insulating member 20, and bonds the inner lateral surface 12C of the second metal member 12 and the second lower lateral surface 22B of the insulating member 20. Accordingly, heat can be easily transferred from the insulating member 20 to the first metal member 11 and the second metal member 12 via the second bonding member 42.

The second bonding member 42 contains, for example, at least one metal selected from copper (Cu), chromium (Cr), nickel (Ni), silver (Ag), aluminum (Al), zinc (Zn), tin (Sn), titanium (Ti), cerium (Ce), zirconium (Zr), and magnesium (Mg). The second bonding member 42 can contain a compound of the above-described metal or an alloy of the above-described metal.

The lower portion 22 of the insulating member 20 further has an upper surface 22C. The upper surface 22C joins the first upper lateral surface 21A with the first lower lateral surface 22A, and joins the second upper lateral surface 21B with the second lower lateral surface 22B. The upper surface 22C joining the first upper lateral surface 21A with the first lower lateral surface 22A faces the first electrode 31 in the third direction Z. The upper surface 22C joining the second upper lateral surface 21B with the second lower lateral surface 22B faces the second electrode 32 in the third direction Z.

The second bonding member 42 can be further located at the upper surface 22C of the lower portion 22 of the insulating member 20, a lower part of the first upper lateral surface 21A, and a lower part of the second upper lateral surface 21B. The second bonding member 42 is disposed continuously at the lower part of the first upper lateral surface 21A, the upper surface 22C, and the first lower lateral surface 22A, and is disposed continuously at the lower part of the second upper lateral surface 21B, the upper surface 22C, and the second lower lateral surface 22B. Accordingly, heat can be more easily transferred from the insulating member 20 to the first metal member 11 and the second metal member 12 via the second bonding member 42.

The second bonding member 42 and the first bonding member 41 are disposed between the upper surface 22C of the lower portion 22 of the insulating member 20 and each of the first electrode 31 and the second electrode 32. Further, when the first metal member 11 includes the plating 13, the plating 13 is disposed between the second bonding member 42 and the first bonding member 41. Between the upper surface 22C of the lower portion 22 of the insulating member 20 and the first electrode 31, the first bonding member 41 is in contact with the first electrode 31 and the second electrode 32, the first bonding member 41 is in direct contact with the second bonding member 42 via the plating 13, and the second bonding member 42 is in contact with the upper surface 22C of the lower portion 22 of the insulating member 20. Accordingly, heat transferred from the semiconductor layered body 33 to the first electrode 31 and the second electrode 32 can also be easily dissipated to the insulating member 20.

The upper surface 21C of the upper portion 21 of the insulating member 20 is exposed from the second bonding member 42. Accordingly, the first bonding member 41 is less likely to wet and spread on the upper surface 21C, and thus a short-circuit between the first electrode 31 and the second electrode 32 via the first bonding member 41 can be made less likely to occur.

At the lower surface of the substrate 10, the lower surface 22D of the lower portion 22 of the insulating member 20 is exposed from the second bonding member 42. Accordingly, in bonding the light source 1 to the mounting substrate, the bonding member is less likely to wet and spread on the lower surface 22D, and thus a short-circuit between the first metal member 11 and the second metal member 12 via the bonding member can be made less likely to occur. Further, the width, in the first direction X, of the lower surface 22D of the lower portion 22 is greater than the width, in the first direction X, of the upper surface 21C of the upper portion 21. Accordingly, the short-circuit between the first metal member 11 and the second metal member 12 can be made further less likely to occur.

The insulating member 20 further includes a metal compound layer 18 at the first lower lateral surface 22A, the second lower lateral surface 22B, the upper surface 22C of the lower portion 22, the first upper lateral surface 21A, and the second upper lateral surface 21B. The adhesion between the insulating member 20 and the first bonding member 41 and the adhesion between the insulating member 20 and the second bonding member 42 can be increased by the metal compound layer 18, and gaps between the insulating member 20 and the first bonding member 41 and between the insulating member 20 and the second bonding member 42 can be made less likely to be formed. Accordingly, heat can be easily transferred between the insulating member 20 and the first electrode 31, between the insulating member 20 and the second electrode 32, between the insulating member 20 and the first metal member 11, and between the insulating member 20 and the second metal member 12.

When the insulating member 20 is a nitride, the metal compound layer 18 can be formed into a metal nitride layer by a thermal reaction between the insulating member 20 and a metal contained in the second bonding member 42, which will be described in a manufacturing method to be described below. For example, the insulating member 20 contains silicon nitride, the second bonding member 42 contains titanium or a titanium compound, and the metal compound layer 18 is a titanium nitride layer.

Alternatively, when the insulating member 20 is an oxide, the metal compound layer 18 can be a metal oxide layer.

Alternatively, when the insulating member 20 is a carbide, the metal compound layer 18 can be a metal carbide layer.

The light source 1 can include a light-transmissive member 34 on the upper surface of the light-emitting device 30 (the second element surface 33B of the semiconductor layered body 33, or the upper surface of the element substrate). The light-transmissive member 34 and the upper surface of the light-emitting device 30 are bonded to each other via a light-transmissive resin layer. Alternatively, the light-transmissive member 34 and the light-emitting surface of light-emitting device 30 can be directly bonded to each other.

As the light-transmissive member 34, for example, a wavelength conversion member, a glass member, a ceramic member, or the like can be used. The light-transmissive member 34 can have a flat-plate shape or a lens shape, and can have an uneven shape on at least one surface. The wavelength conversion member converts the wavelength of at least a part of light emitted by the active layer of the semiconductor layered body 33. As the wavelength conversion member, a sintered compact can be used that is formed by sintering powder of a phosphor so as to be substantially made of only the phosphor. Alternatively, as the wavelength conversion member, a light-transmissive material containing a phosphor can be used. Examples of the light-transmissive material that can be used include a ceramic, a resin, and a glass. Examples of the phosphor that can be used include a cerium-activated yttrium-aluminum-garnet-based phosphor (for example, (Y,Gd)₃(Al,Ga)₅O₁₂:Ce), and a cerium-activated lutetium-aluminum-garnet-based phosphor (for example, Lu₃(Al,Ga)₅O₁₂:Ce).

The light source 1 can further include a covering member 50. The covering member 50 can have reflectivity with respect to the light emitted by the active layer. For example, the covering member 50 includes a light-transmissive base material and light-reflective particles dispersed in the base material. As the material of the base material, a resin, glass, or a ceramic can be used. Examples of the light-reflective particles include titanium oxide, silicon oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, and zirconium oxide. When the light-emitting device 30 is an LD, the covering member 50 need not necessarily be provided.

The outer lateral surface 11D of the first metal member 11 and the outer lateral surface 12D of the second metal member 12 are preferably exposed from the covering member 50. A bonding member, which is used in bonding the light source 1 to the mounting substrate, can wet and rise up the exposed outer lateral surfaces 11D and 12D. Accordingly, heat generated by the light-emitting device 30 can be dissipated to the mounting substrate from the outer lateral surface 11D of the first metal member 11 via the bonding member, and from the outer lateral surface 12D of the second metal member 12 via the bonding member.

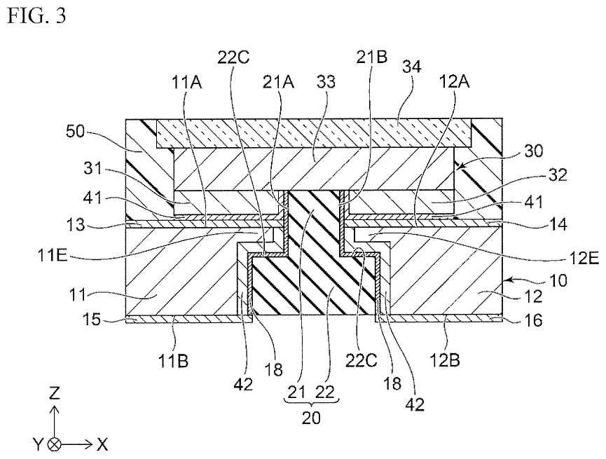

As illustrated in FIG. 3, a portion 11E of the first metal member 11 can be located between the upper surface 22C of the lower portion 22 of the insulating member 20 and the first electrode 31, and a portion 12E of the second metal member 12 can be located between the upper surface 22C of the lower portion 22 of the insulating member 20 and the second electrode 32. Accordingly, an area in which the first electrode 31 and the first metal member 11 face each other and an area in which the second electrode 32 and the second metal member 12 face each other can be increased, and thus heat dissipation from the first electrode 31 and the second electrode 32 to the first metal member 11 and the second metal member 12 can be improved.

### Manufacturing Method of Substrate

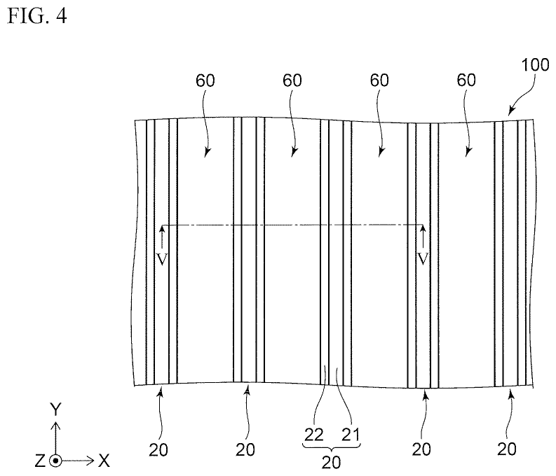

Next, an example of a method for manufacturing the substrate 10 will be described with reference to FIGS. 4 to 11.

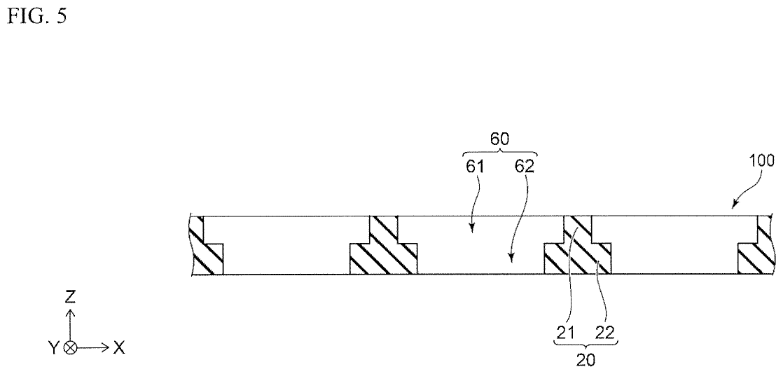

As illustrated in FIGS. 4 and 5, the method for manufacturing the substrate 10 includes a step of preparing a ceramic sintered compact 100. FIG. 5 is a schematic cross-sectional view taken along a line V-V in FIG. 4.

The ceramic sintered compact 100 includes a plurality of the insulating members 20 extending in the second direction Y and arranged side by side so as to be spaced apart from each other in the first direction X. A through hole portion 60 extending in the second direction Y is located between the insulating members 20 adjacent to each other in the first direction X. As illustrated in FIG. 5, the through hole portion 60 includes a first hole portion 61 adjacent to the upper portion 21 of the insulating member 20, and a second hole portion 62 adjacent to the lower portion 22 of the insulating member 20. The first hole portion 61 and the second hole portion 62 are connected to each other in the third direction Z. The width of the first hole portion 61 in the first direction X is greater than the width of the second hole portion 62 in the first direction X. For example, end portions of the plurality of insulating members 20 in the second direction Y are integrally connected to a coupling member extending in the first direction X.

The step of preparing the ceramic sintered compact 100 can include a step of forming the through hole portion 60 in a ceramic plate, which is a sintered compact subjected to a baking treatment, using a method such as laser processing or blade processing. By forming the through hole portion 60 in the ceramic plate, which is the sintered compact, using the above-described processing method, it is possible to form the plurality of insulating members 20 in which variations in the shape are reduced.

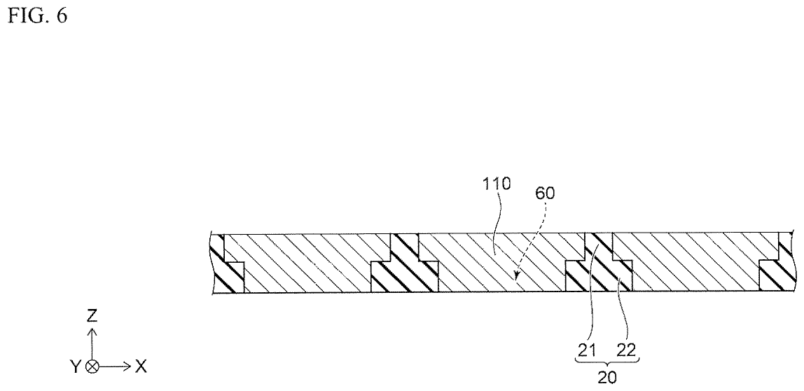

As illustrated in FIG. 6, the method of manufacturing the substrate 10 includes a step of filling the through hole portion 60 with a metal paste 110.

The metal paste 110 contains, for example, at least one metal selected from copper (Cu), chromium (Cr), nickel (Ni), silver (Ag), aluminum (Al), zinc (Zn), tin (Sn), titanium (Ti), cerium (Ce), zirconium (Zr), and magnesium (Mg). Further, the metal paste 110 can contain a compound of the above metal or an alloy of the above metal. Further, the metal paste 110 contains active metal powder. The active metal powder can be at least one selected from TiH₂, CeH₂, ZrH₂, and MgH₂. Further, the metal paste 110 can contain an organic solvent. The viscosity of the metal paste 110 can be adjusted in accordance with the type and amount of the organic solvent. As the organic solvent, for example, a resin such as acrylic, epoxy, urethane, ethyl cellulose, silicone, phenol, polyimide, polyurethane, melamine, or urea can be used. The metal paste 110 can contain an inorganic filler. When the metal paste 110 contains the inorganic filler, volumetric shrinkage in a baking treatment described below can be reduced. As the inorganic filler, for example, aluminum nitride (AlN), silicon nitride (Si₃N₄), aluminum oxide (Al₂O₃), or the like can be used. As an example, the metal paste 110 preferably contains an silver-copper alloy with a mixing ratio of silver (Ag) and copper (Cu) of 72:28 in a range from 60 wt. % to 99 wt. %, titanium hydroxide (TiH₂) as active metal powder in a range from 0.5 wt. % to 10 wt. %, an organic binder in a range from 0.1 wt. % to 10 wt. %, and an inorganic filler in a range from 1 wt. % to 20 wt. %.

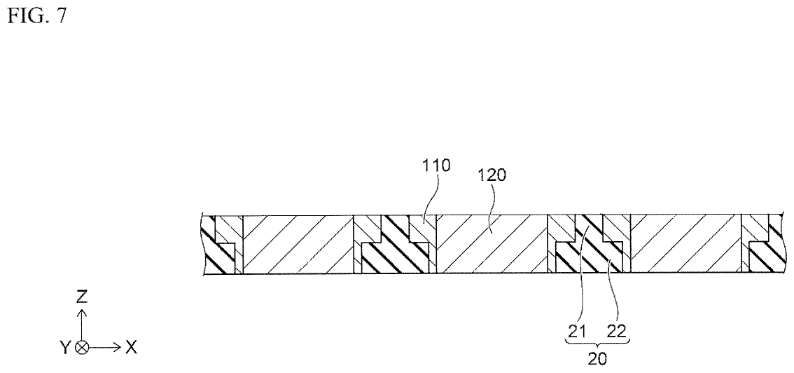

As illustrated in FIG. 7, the method of manufacturing the substrate 10 includes a step of disposing a metal body 120 in the metal paste 110. The metal body 120 extends in the second direction Y. A plurality of the metal bodies 120 can be prepared from a metal plate, for example, using a method such as punching, laser machining, etching, or the like. The cross-sectional shape, the upper surface shape, and the lower surface shape of the metal body 120 are rectangular or square. Accordingly, the plurality of metal bodies 120, in which variations in the shape are reduced, can be prepared from the metal plate using the above-described method. In a step described below, the metal body 120 is diced along the first direction X and the second direction Y in a plan view, so as to be separated into the above-described first metal member 11 and second metal member 12.

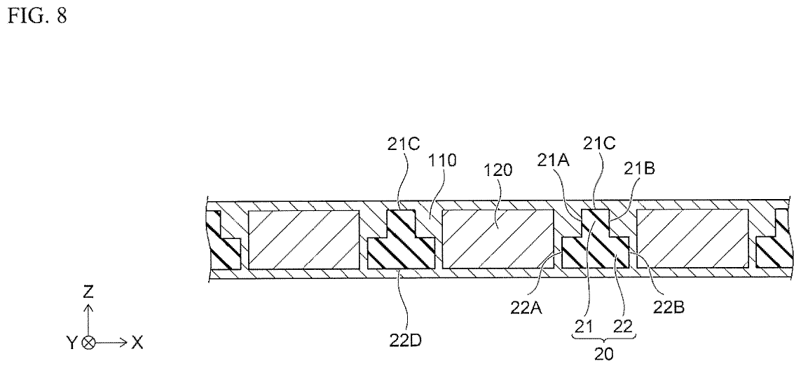

The method of manufacturing the substrate 10 can include, after disposing the metal body 120 in the metal paste 110, as necessary, a step of further forming the metal paste 110 so as to cover the upper surface of the metal body 120, the lower surface of the metal body 120, the upper surface 21C of the upper portion 21 of the insulating member 20, and the lower surface 22D of the lower portion 22 of the insulating member 20, as illustrated in FIG. 8. Accordingly, volumetric shrinkage of a metal body (second bonding member 42) described below can be reduced. The metal body is obtained by performing a baking treatment on the metal paste 110.

The method of manufacturing the substrate 10 includes, after disposing the metal body 120 in the metal paste 110, a step of performing a baking treatment in which the metal paste 110 is baked at a temperature in a range from 780° C. to 850° C., for example. By the baking treatment, the organic solvent in the metal paste 110 is evaporated, and further, the powder of the metal or the alloy is melted to form the second bonding member 42, which is a continuous metal body.

For example, when the metal paste 110 contains silver-copper alloy powder as the main component, the melting point of the silver-copper alloy powder is 780° C., which is lower than the melting point (1084° C.) of copper powder and the melting point (962° C.) of silver powder, and thus the baking treatment can be performed at a lower temperature than that when the metal paste 110 contains the copper powder or the silver powder as the main component.

Further, by the baking treatment, the metal contained in the metal paste 110 and the insulating member 20 thermally react with each other, and the metal compound layer 18 is formed on the surfaces of the insulating member 20, which have been in contact with the metal paste 110 (the first upper lateral surface 21A, the second upper lateral surface 21B, the first lower lateral surface 22A, the second lower lateral surface 22B, and the upper surface 22C of the lower portion 22). The metal compound layer 18 increases the bonding force between the insulating member 20 and the second bonding member 42. For example, when the insulating member 20 contains silicon nitride, and the metal paste 110 contains titanium hydride as the active metal powder, a titanium nitride layer is formed as the metal compound layer 18.

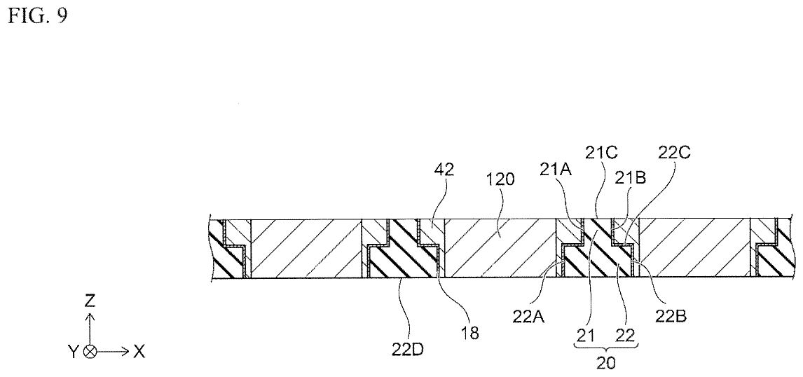

After the baking treatment, the second bonding member 42, which covers the upper surface of the metal body 120, the lower surface of the metal body 120, the upper surface 21C of the upper portion 21 of the insulating member 20, and the lower surface 22D of the lower portion 22 of the insulating member 20, is removed by a polishing treatment. Accordingly, as illustrated in FIG. 9, the upper surface of the metal body 120, the lower surface of the metal body 120, the upper surface 21C of the upper portion 21 of the insulating member 20, and the lower surface 22D of the lower portion 22 of the insulating member 20 are exposed from the second bonding member 42. The metal body 120 is bonded, by the second bonding member 42, to the first upper lateral surface 21A, the second upper lateral surface 21B, the first lower lateral surface 22A, and the second lower lateral surface 22B of the insulating member 20.

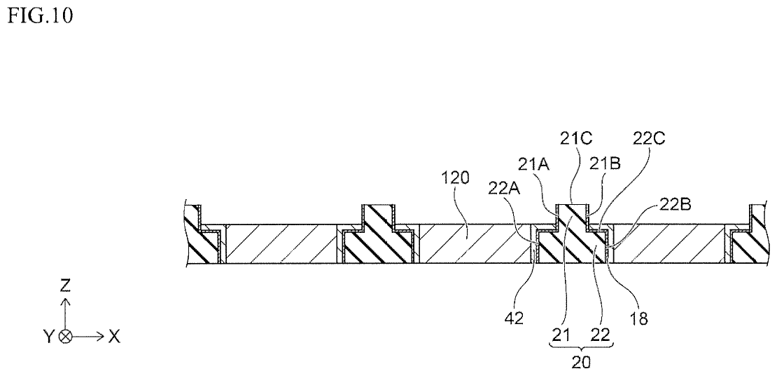

The method for manufacturing the substrate 10 includes, after the above-described baking treatment, a step of removing a part of the upper surface side of the metal body 120 and a part of the upper surface side of the second bonding member 42 to expose a part of the first upper lateral surface 21A and a part of the second upper lateral surface 21B of the insulating member 20 from the second bonding member 42, as illustrated in FIG. 10. For example, the metal body 120 and the second bonding member 42 can be removed using a method such as etching or blasting.

The metal compound layer 18 is not removed and remains at the first upper lateral surface 21A and the second upper lateral surface 21B exposed from the second bonding member 42. Accordingly, the above-described first bonding member 41 easily wets and spreads on the metal compound layer 18.

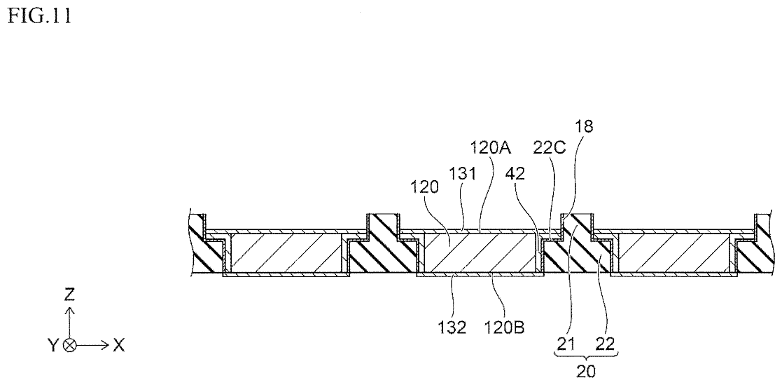

The method of manufacturing the substrate 10 can include a step of forming a plating 131 and a plating 132, as illustrated in FIG. 11, as necessary. The plating 131 and the plating 132 can be formed by electrolytic plating or electroless plating. The plating 131 is formed at the upper surface of the metal body 120, and the plating 132 is formed at the lower surface of the metal body 120. At a time of dicing the metal body 120, the plating 131 is separated into the above-described plating 13 and plating 14, and the plating 132 is separated into the above-described plating 15 and plating 16.

### Method for Bonding Light-Emitting Device to Substrate

The first bonding member 41 is supplied to the upper surface of the metal body 120 of the substrate 10 obtained by the steps described above, and the light-emitting device 30 is disposed on the substrate 10 such that the upper portion 21 of the insulating member 20 is located between the first electrode 31 and the second electrode 32 of the light-emitting device 30. Each of the first electrode 31 and the second electrode 32 is disposed on the first bonding member 41. There are gaps between the first upper lateral surface 21A of the insulating member 20 and the inner lateral surface of the first electrode 31 and between the second upper lateral surface 21B of the insulating member 20 and the inner lateral surface of the second electrode 32. In this state, a reflow treatment is performed in which the first bonding member 41 is heated and melted.

The melted first bonding member 41 wets and spreads between the first electrode 31 and the metal body 120 and between the second electrode 32 and the metal body 120, and further wets and rises up between the first upper lateral surface 21A of the insulating member 20 and the inner lateral surface of the first electrode 31 and between the second upper lateral surface 21B of the insulating member 20 and the inner lateral surface of the second electrode 32. When the first bonding member 41 is cured after the reflow treatment, the first electrode 31 and the metal body 120 are bonded to each other, the second electrode 32 and the metal body 120 are bonded to each other, the first electrode 31 and the upper portion 21 of the insulating member 20 are bonded to each other, and the second electrode 32 and the upper portion 21 of the insulating member 20 are bonded to each other.

Since the upper portion 21 of the insulating member 20 is located between the first electrode 31 and the second electrode 32 of the light-emitting device 30, it is possible to restrict rotation of the light-emitting device 30 in the XY plane and a large positional shift of the light-emitting device 30 in the first direction X at a time of bonding during which the first bonding member 41 is melted and has fluidity.

After the light-emitting device 30 is bonded to the substrate 10, outer lateral surfaces of the light-emitting device 30 are covered with the covering member 50, as necessary. Thereafter, the metal body 120 is diced along the first direction X and the second direction Y, and the insulating member 20 is also cut at the dicing positions of the metal body 120 along the first direction X. As a result, a plurality of the singulated light sources 1 are obtained.

The embodiments of the present invention have been described above with reference to specific examples. However, the present invention is not limited to these specific examples. All aspects that can be practiced by a person skilled in the art changing the design as appropriate based on the above-described embodiments of the present invention are also included in the scope of the present invention, as long as they encompass the spirit of the present invention. In addition, in the spirit of the present invention, a person skilled in the art can conceive of various variations and modifications, and those variations and modifications will also fall within the scope of the present invention.

1. A light source comprising:
a substrate;
a light-emitting device disposed on the substrate; and
a first bonding member disposed between the substrate and the light-emitting device, wherein
the substrate comprises
a first metal member having a first upper surface and a first lower surface located on a side opposite to the first upper surface,
a second metal member having a second upper surface and a second lower surface located on a side opposite to the second upper surface, the second metal member being spaced apart from the first metal member in a first direction, and
an insulating member comprising a lower portion located between the first metal member and the second metal member in the first direction, and an upper portion extending, from the lower portion, to be higher than the first upper surface and the second upper surface,
the light-emitting device comprises
a semiconductor layered body having a first element surface facing the substrate and a second element surface located on a side opposite to the first element surface,
a first electrode disposed at the first element surface, and
a second electrode disposed at the first element surface to be spaced apart from the first electrode in the first direction,
the first bonding member
is disposed between the first electrode and the first upper surface of the first metal member and bonds the first electrode and the first metal member, and
is disposed between the second electrode and the second upper surface of the second metal member and bonds the second electrode and the second metal member,
the upper portion of the insulating member is located between the first electrode and the second electrode in the first direction, and
the lower portion of the insulating member is exposed.

2. The light source according to claim 1, wherein
the upper portion of the insulating member has a first upper lateral surface facing an inner lateral surface of the first electrode,
the upper portion of the insulating member has a second upper lateral surface facing an inner lateral surface of the second electrode,
the first bonding member bonds the inner lateral surface of the first electrode and an upper part of the first upper lateral surface of the insulating member, and
the first bonding member bonds the inner lateral surface of the second electrode and an upper part of the second upper lateral surface of the insulating member.

3. The light source according to claim 2, wherein
the lower portion of the insulating member has a first lower lateral surface facing an inner lateral surface of the first metal member,
the lower portion of the insulating member has a second lower lateral surface facing an inner lateral surface of the second metal member,
the substrate further comprises a second bonding member bonding the inner lateral surface of the first metal member and the first lower lateral surface, and
the second bonding member bonding the inner lateral surface of the second metal member and the second lower lateral surface.

4. The light source according to claim 3, wherein
the second bonding member is further provided at an upper surface of the lower portion of the insulating member, a lower part of the first upper lateral surface, and a lower part of the second upper lateral surface.

5. The light source according to claim 1, wherein
a width, in the first direction, of the lower portion of the insulating member is greater than a width, in the first direction, of the upper portion of the insulating member.

6. The light source according to claim 3, wherein
a width, in the first direction, of the lower portion of the insulating member is greater than a width, in the first direction, of the upper portion of the insulating member, and
at a lower surface of the substrate, a width, in the first direction, of the lower portion of the insulating member exposed from the second bonding member is greater than a width, in the first direction, of the upper portion of the insulating member exposed from the second bonding member.

7. The light source according to claim 1, wherein
an upper surface of the upper portion of the insulating member is in contact with the first element surface of the light-emitting device.

8. The light source according to claim 1, wherein
the insulating member is made of a ceramic.

9. The light source according to claim 4, wherein
the insulating member further comprises a metal compound layer at the first lower lateral surface, the second lower lateral surface, the upper surface of the lower portion of the insulating member, the first upper lateral surface, and the second upper lateral surface.

10. The light source according to claim 9, wherein
the insulating member contains silicon nitride,
the second bonding member contains titanium or a titanium compound, and
the metal compound layer is a titanium nitride layer.

11. The light source according to claim 1, wherein
the insulating member is formed by covering a metal with a ceramic, glass, or a resin.

12. The light source according to claim 1, wherein
the first lower surface of the first metal member and the second lower surface of the second metal member are exposed.

13. The light source according to claim 1, wherein
the first metal member includes a first plating,
a lower surface of the first plating forms the first lower surface of the first metal member,
the second metal member includes a second plating,
a lower surface of the second plating forms the second lower surface of the second metal member, and
the lower surface of the first plating and the lower surface of the second plating are exposed.

14. A substrate comprising:
a first metal member having a first upper surface and a first lower surface located on a side opposite to the first upper surface;
a second metal member having a second upper surface and a second lower surface located on a side opposite to the second upper surface, the second metal member being spaced apart from the first metal member in a first direction; and
an insulating member comprising a lower portion located between the first metal member and the second metal member in the first direction, and an upper portion extending, from the lower portion, to be higher than the first upper surface and the second upper surface, wherein
a width, in the first direction, of the lower portion of the insulating member is greater than a width, in the first direction, of the upper portion of the insulating member,
the lower portion of the insulating member has a first lower lateral surface facing an inner lateral surface of the first metal member,
the lower portion of the insulating member has a second lower lateral surface facing an inner lateral surface of the second metal member,
the substrate further comprises a bonding member bonding the inner lateral surface of the first metal member and the first lower lateral surface,
the bonding member bonding the inner lateral surface of the second metal member and the second lower lateral surface, and
the bonding member being located at an upper surface of the lower portion of the insulating member.

15. The substrate according to claim 14, wherein
the insulating member is made of a ceramic, and
the substrate further comprises a metal compound layer provided at an interface between the insulating member and the bonding member.
